(19) United States
(12) Patent Application Publication
(10) Pub. No.: US 2013/0025903 A1
(43) Pub. Date: Jan. 31, 2013

(54) ELECTRIC DEVICE COMPRISING MOTOR IN HOUSING BODY

(71) Applicants: Takashi Yamaguchi, Shiga (JP); Hitoshi OGAWA, Shiga (JP)

(72) Inventors: Takashi Yamaguchi, Shiga (JP); Hitoshi OGAWA, Shiga (JP)

(21) Appl. No.: 13/531,421

(22) Filed: Jun. 22, 2012

(30) Foreign Application Priority Data
Jul. 25, 2011 (JP) 2011-161656

(51) Int. Cl. H05K 5/00

(52) U.S. Cl. 174/50

(57) ABSTRACT

An electric device has a housing body (1) comprised of first and second housings (11, 12) and a motor (2) in the body (1). The housings (11, 12) are divided along one direction (A). The electric device includes first and second rings (6 and 7) that are attached to different first and second places on an outer circumferential surface of the housings (11 and 12), respectively, to combine them with each other. The first and second places correspond to first and second end sides of an axis of the motor (2), respectively.

### TECHNICAL FIELD

The invention relates generally to small electric devices and, more particularly, to a small electric device comprising a motor built in a thin tubular housing body.

### BACKGROUND ART

There are small electric devices such as nose hair trimmers, eyebrow trimmers or electric toothbrushes, each of which includes a cylindrical motor built in a thin tubular housing body (e.g., Japanese Patent Application Publication No. 2011-62447). For example, a housing body extends in one direction and a motor is put in the housing body which is comprised of two housings (housing halves) divided along the one direction. The two housings are combined with each other after the motor is put in them. They are combined by engaging a hook in one of the two housings with another hook in the other, or using screws. In this case, it is necessary to prepare space for hooks or insertion regions of the screws between an inner circumferential surface of the housing body and an outer circumferential surface of the motor, thereby enlarging an external diameter of the housing body in comparison with an external diameter of the motor. There is moreover a problem that the motor generates a resonance sound that causes a large noise if a gap is present between the inner circumferential surface of the housing body and the outer circumferential surface of the motor. If the hooks or the insertion regions are placed away from the motor area, the external diameter of the housing body can be decreased, but it is necessary to lengthen the whole length of the housing body in the aforementioned one direction.

In addition, when the hooks are used, there is a problem that the housing body becomes hard to be disassembled, which causes troublesome task. Because hook strength is increased in order to prevent hooks from being released by impact.

### SUMMARY OF INVENTION

It is an object of the present invention to provide an electric device capable of: thinning and shortening a housing body in which a motor is built; and easily assembling and disassembling the housing body.

The present invention is an electric device comprising a housing body (1) and a motor (2). The housing body (1) extends in one direction (A) and is comprised of first and second housings (11 and 12) divided along the one direction (A). The motor (2) is in the housing body (1). The electric device further comprises at least first and second rings (6 and 7) that are attached to different first and second places on an outer circumferential surface of the first and second housings (11 and 12), respectively, to combine them (11 and 12) with each other. The first and second places corresponds to first and second end sides of an axis of the motor (2), respectively.

In an embodiment, the electric device further comprises first and second members (50 and 4) that are attached to first and second ends of the housing body (1) in said one direction (A) by bayonet coupling, respectively, to retain and fix the first and second rings (6 and 7).

In an embodiment, an outer circumferential surface of the motor (2) is in contact with an inner circumferential surface of the housing body (1) with no space between them (1 and 2).

In an embodiment, at least one of the first and second rings (6 and 7) is a cosmetic ring having accented appearance.

In an embodiment, the electric device further comprises: a switch handle (8) that is placed on an outer circumferential surface of one of the first and second rings (6 and 7) and slidable in said one direction (A); and a cap (3) that is detachably attached to an outer circumference of the housing body (1) in said direction (A). The cap (3) holds the switch handle (8) at an OFF-position by pressing the switch handle (8) with an end edge of the cap (3) when the cap (3) is attached to the housing body (1).

In the present invention, it is possible to combine the first and second housing easily and surely in comparison with divided two housings which are combined with each other through hooks, screws or the like. It is also unnecessary to prepare space for the hooks or the screws in the housing body, thereby decreasing an external diameter of the housing body in comparison with an external diameter of the motor, while shortening a dimension in the aforementioned one direction. The housing body can be disassembled by simply detaching the first and second rings, thereby facilitating a disassembling procedure and providing excellent maintenance.

### BRIEF DESCRIPTION OF DRAWINGS

Preferred embodiments of the invention will now be described in further details. Other features and advantages of the present invention will become better understood with regard to the following detailed description and accompanying drawings where:

FIGS. 1A, 1B and 1C illustrate a small electric device in accordance with an embodiment of the present invention, and are front, side and longitudinal sectional views of the device, respectively;

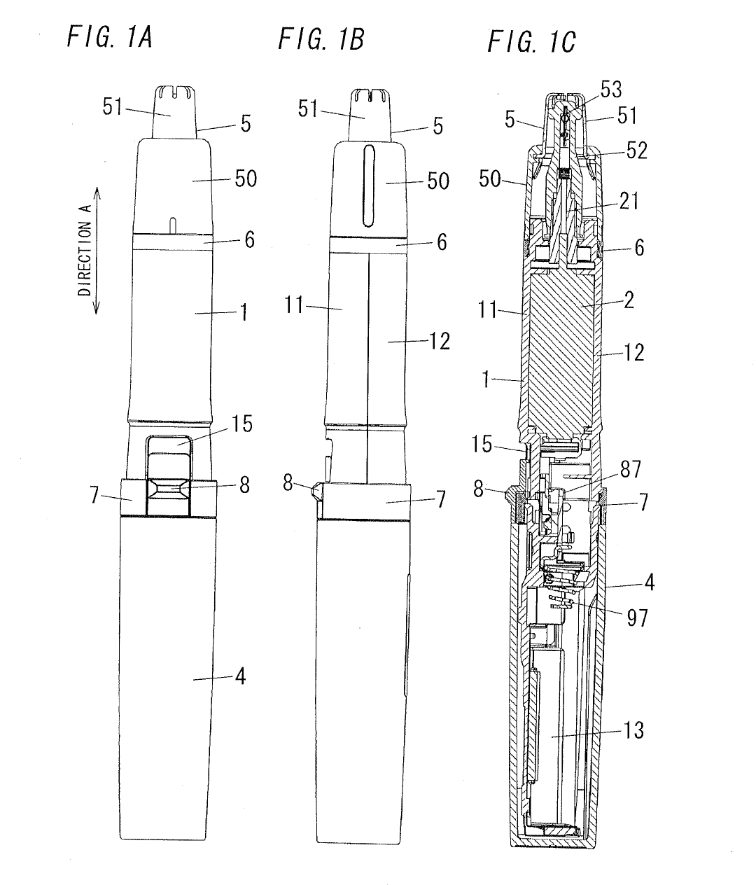

FIG. 2 is an exploded perspective view of the device;

FIG. 3 illustrates an assembling sequence of the device;

FIG. 4A is a longitudinal sectional view of part around a motor of the device, and FIG. 4B is a transverse sectional view of part around the motor;

FIG. 5 is a longitudinal sectional view of part around a switch of the device; and

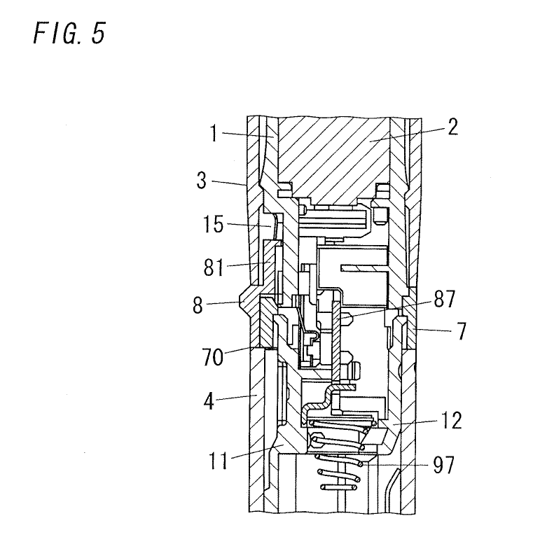

FIGS. 6A, 6B and 6C illustrate the device equipped with a cap, and are front, side and longitudinal sectional views of the device, respectively.

### DESCRIPTION OF EMBODIMENTS

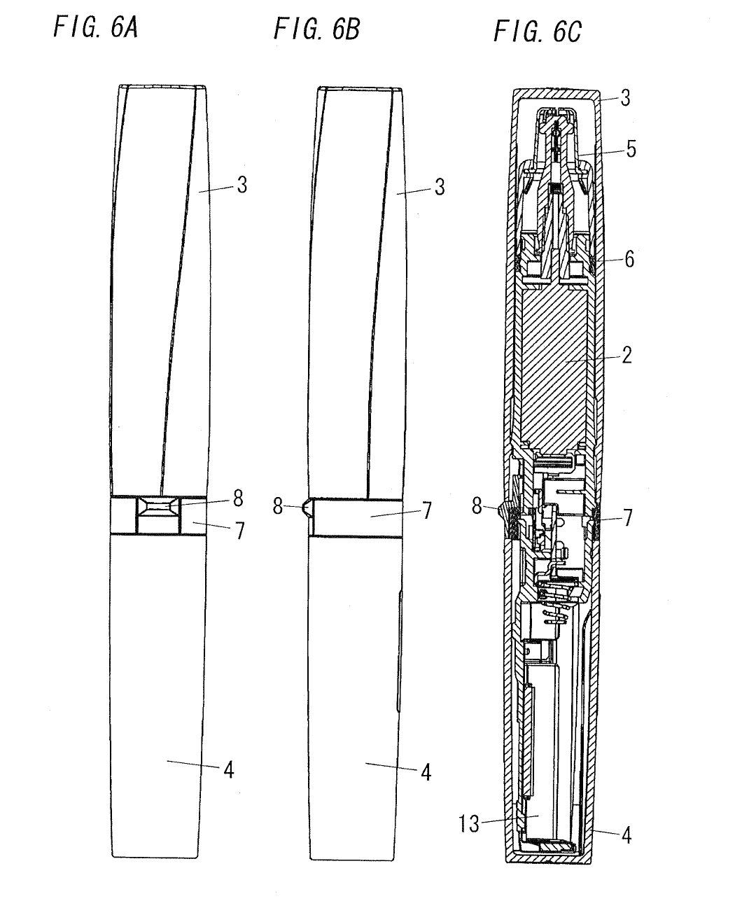

An embodiment of the present invention is explained in detail. An electric device illustrated in the figures is, for example, a nose hair trimmer and includes a housing body 1 which is shaped like a cylinder, a long thin motor 2 which is shaped like a cylinder and built in the housing body 1, and a blade block (cutter) 5 placed at a first end of the housing body 1. In the embodiment, the housing body 1 extends in one direction (A) and has a cylindrical part and a half cylindrical part at first and second end sides of the housing body 1, respectively. As shown in FIGS. 6A-6C, the electric device further includes a cap 3 which is shaped like a cylinder with a base (e.g., an upper base) and is detachably attached to the first end side of the housing body 1, and a battery cover 4 (a second member) which is shaped like a cylinder with a base (e.g., a lower base) and is capped over the second end side of the housing body 1.

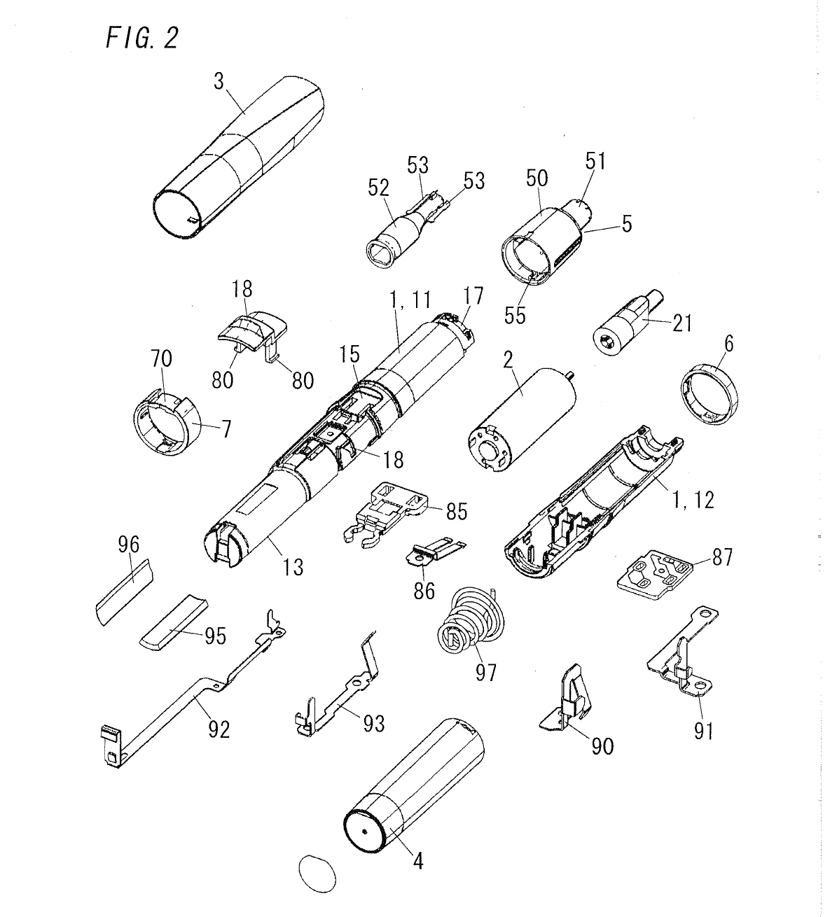

The housing body 1 is formed of first and second housings (housing halves) 11 and 12 divided along the direction (A). The first housing 11 has a battery chamber 13 and is longer by the battery chamber 13 than the second housing 12. As shown in FIG. 2, besides the motor 2, the electric device further includes: a printed board 87; metallic parts 91, 93 connecting between both poles (terminals) of the motor 2 and the printed board 87; metallic parts 90, 92 connecting between both electrodes of a battery in the battery chamber 13 and the printed board 87; a slide board 85 with a contact spring 86; and the like, which are built between the first and second housings 11 and 12. In FIG. 2, 95 is a cushion material placed in the battery chamber 13, 96 is a label on which battery orientation is printed, and 97 is a battery contact spring.

The blade block 5 is attached to the first end of the housing body 1 formed of the housings 11 and 12. The blade block 5 includes an outer blade flame 50 (a first member) having an outer blade 51 and an inner blade flame 52 having an inner blade 53. The inner blade flame 52 is coupled to an output axis of the motor 2 through a joint 21. The outer blade flame 50 has a projection(or projections) 55 formed on the inner face of the flame 50, while the housing body 1 has a catching groove (or catching grooves) 17 formed on the outer circumferential surface of the first end of the body 1. The projection 55 is combined with the catching groove 17 by bayonet coupling, and thereby the outer blade flame 50 is combined with the housing body 1.

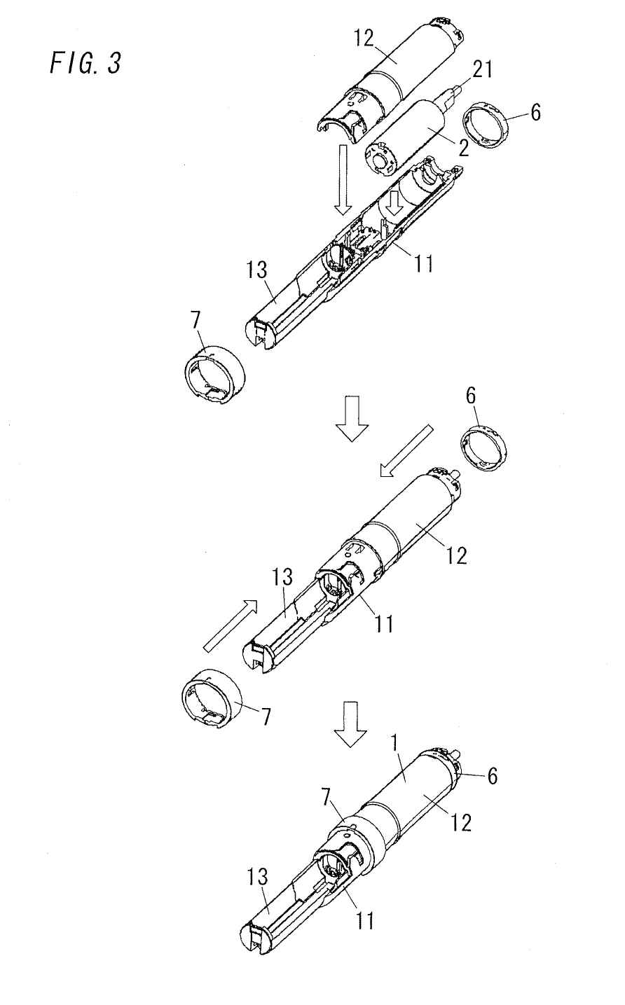

The housings 11 and 12 divided along the direction (A) are combined with each other through first and second rings 6 and 7 as shown in FIG. 3, thereby constituting the housing body 1. That is, the first and second rings 6 and 7 are attached to different first and second places on an outer circumferential surface of the first and second housings 11 and 12, respectively, to combine them with each other. The first and second places correspond to first and second end sides of an axis of the motor (2), respectively, and the first end side corresponds to the output axis of the motor 2. The first ring 6 has the same external diameter as a large diameter part of the housing body 1, while the housing body 1 (housing 11 and 12) has a first thin part cover with the first ring 6 at the first end side of the body 1. The housing body 1 (housing 11 and 12) also has a second thin part cover with the second ring 7 at an intermediate part of the body 1 (between the battery chamber 13 and a motor chamber in which the motor 2 is put). In short, the cylindrical part of the housing body 1 has the first small diameter part and the second small diameter part at the first end side and the second end side of the body 1, respectively and also has the large diameter part between the first and second small diameter parts. The large diameter part is slightly larger than the first and second small diameter parts and includes the motor chamber.

The color of the first ring 6 has the same as those of the housing body 1 and the outer blade flame 50. The first ring 6 is present between the large diameter part of the housing body 1 and the outer blade flame 50 combined with the first end of the housing body 1 by bayonet coupling. That is, the first ring 6 is retained and fixed with the outer blade flame 50 by attaching the flame 50 to the housing body 1.

The second ring 7 is present between the battery cover 4 and the large diameter part of the housing body 1. The housing body 1 has a catching groove 18 on the outer circumferential surface of the body 1, and the battery cover 4 has a projection (not shown) on the inner face of the cover 4. Accordingly, the second ring 7 is retained and fixed with the battery cover 4 by coupling the projection to the catching groove 18 by bayonet coupling. The second ring 7 has an external diameter slightly larger than that of the large diameter part of the housing body 1, and also has almost the same external diameter as that of the battery cover 4. The cap 3 is detachably attached to the first end side of the housing body 1 to cover the blade block 5. The cap 3 has almost the same external diameter as that of the second ring 7. Therefore, when the cap 3 and the battery cover 4 are attached to the housing body 1, the second ring 7 becomes exposed between the cap 3 and the battery cover 4, but all of them are continuously arranged almost without bump or step in the direction (A) as shown in FIGS. 6A-6C. The second ring 7 is also finished in a different color from the housing body 1, the cap 3 and the battery cover 4, thereby functioning as an accent ring (a cosmetic ring) in appearance.

In the embodiment, a slide type of switch handle 8 is placed on a part of the second ring 7. The switch handle 8 is put in a groove 70 provided on the outer circumferential surface of the second ring 7 along the direction (A). The switch handle 8 has legs 80 and 80 that are inserted into holes of the housing body 1 to be combined with the slide board 85. A part of the switch handle 8 is placed in a recess 15 formed on the exterior surface of the housing body 1 in order to prevent interference with the cap 3.

If the switch handle 8 is slit, the slide board 85 having the contact spring 86 is slit in interlock with the handle 8. That is, the contact spring 86 is slit on a pattern of the printed board 87, thereby enabling and disabling operation of the motor 2 (enabling and disabling current supply to the motor 2).

When the cap 3 is attached to the housing body 1, the groove 70 is formed on the second ring 7 between both edge faces of the cap 3 and the battery cover 4, and a part of the switch handle 8 is kept in the groove 70. That is, the part of the switch handle 8 is pushed with the edge face of the cap 7, and the handle 8 is fixed at an OFF-position. Therefore, unless the cap 3 is detached from the housing body 1, the energization to the motor 2 is stopped. If the cap 3 is attached to the housing body 1 with the switch handle 8 present at an ON-position, the switch handle 8 is returned to the OFF-position.

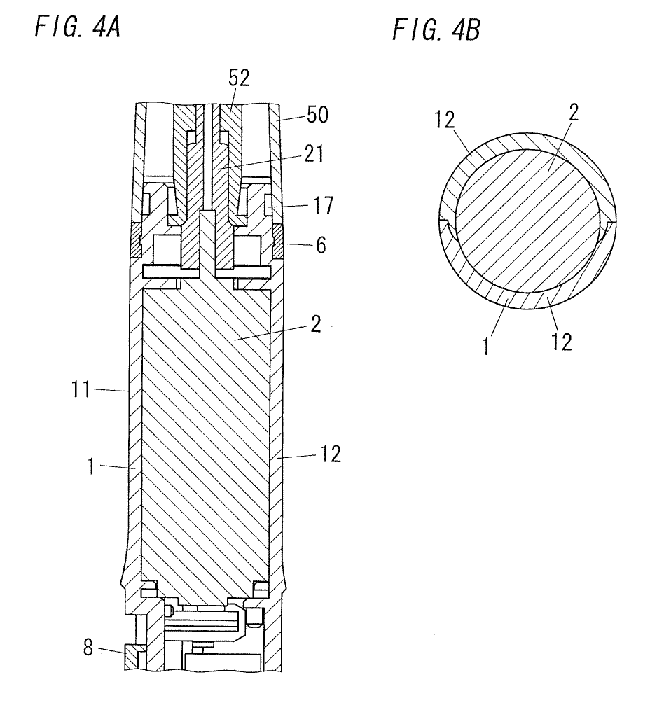

In the small electric device, the housing body 1 shaped like a cylinder is formed of the first and second housings 11 and 12 divided along the direction (A). The housings 11 and 12 are combined with each other through the first and second rings 6 and 7 placed at positions in the direction (A) which are not overlapped with the motor 2. The housing 11 and 12 do not require any space or members inside them, for coupling the housing 11 and 12. Therefore, the inner circumferential surface of the housing body 1 can be in contact with the outer circumferential surface of the motor 4 with no space between them as shown in FIG. 4B, and the diameter of the housing body 1 can be decreased. In addition, it is possible to solve the aforementioned problem that the motor generates a resonance sound that causes a large noise if a gap is present between the inner circumferential surface of the housing body and the outer circumferential surface of the motor. That is, the embodiment has an advantage of silent operation.

The first and second rings 6 and 7 are retained and fixed with the outer blade flame 50 and the battery cover 4 which are attached to the housing body 1 by bayonet coupling, thereby discarding additional members for retaining the rings 6 and 7 and preventing the rings 6 and 7 from being easily released. Moreover, if the bayonet coupling of the outer blade flame 50 and the battery cover 4 with respect to the housing body 1 is released, it is possible to easily detach the rings 6 and 7 to disassemble the housing body 1. The outer blade flame 50 and the battery cover 4 can be detachably attached to the housing body 1 with no tool. Therefore, the embodiment has excellent maintenance.

The embodiment is an example of the nose hair trimmer, but the present invention can be applied to any kind of electric devices if having a long thin housing body 1 in which a motor 2 is put. In addition, a third ring (not shown) may be adjacent to one of the first and second rings 6 and 7.

Although the present invention has been described with reference to certain preferred embodiments, numerous modifications and variations can be made by those skilled in the art without departing from the true spirit and scope of this invention, namely claims.

1. An electric device, comprising:
a housing body that extends in one direction and is comprised of first and second housings divided along the one direction; and
a motor in the housing body,
wherein the electric device further comprises at least first and second rings that are attached to different first and second places on an outer circumferential surface of the first and second housings, respectively, to combine them with each other, said first and second places corresponding to first and second end sides of an axis of the motor, respectively.

2. The electric device of claim 1, further comprising first and second members that are attached to first and second ends of the housing body in said one direction by bayonet coupling, respectively, to retain and fix the first and second rings.

3. The electric device of claim 1, wherein an outer circumferential surface of the motor is in contact with an inner circumferential surface of the housing body with no space between them.

4. The electric device of claim 2, wherein an outer circumferential surface of the motor is in contact with an inner circumferential surface of the housing body with no space between them.

5. The electric device of claim 1, wherein at least one of the first and second rings is a cosmetic ring having accented appearance.

6. The electric device of claim 2, wherein at least one of the first and second rings is a cosmetic ring having accented appearance.

7. The electric device of claim 3, wherein at least one of the first and second rings is a cosmetic ring having accented appearance.

8. The electric device of claim 1, further comprises:
a switch handle that is placed on an outer circumferential surface of one of the first and second rings and slidable in said one direction; and
a cap that is detachably attached to an outer circumference of the housing body in said direction,
wherein the cap holds the switch handle at an OFF-position by pressing the switch handle with an end edge of the cap when the cap is attached to the housing body.

9. The electric device of claim 2, further comprises:
a switch handle that is placed on an outer circumferential surface of one of the first and second rings and slidable in said one direction; and
a cap that is detachably attached to an outer circumference of the housing body in said direction,
wherein the cap holds the switch handle at an OFF-position by pressing the switch handle with an end edge of the cap when the cap is attached to the housing body.

10. The electric device of claim 3, further comprises:
a switch handle that is placed on an outer circumferential surface of one of the first and second rings and slidable in said one direction; and
a cap that is detachably attached to an outer circumference of the housing body in said direction,
wherein the cap holds the switch handle at an OFF-position by pressing the switch handle with an end edge of the cap when the cap is attached to the housing body.

11. The electric device of claim 4, further comprises:
a switch handle that is placed on an outer circumferential surface of one of the first and second rings and slidable in said one direction; and
a cap that is detachably attached to an outer circumference of the housing body in said direction,
wherein the cap holds the switch handle at an OFF-position by pressing the switch handle with an end edge of the cap when the cap is attached to the housing body.

12. The electric device of claim 5, further comprises:
a switch handle that is placed on an outer circumferential surface of one of the first and second rings and slidable in said one direction; and
a cap that is detachably attached to an outer circumference of the housing body in said direction,
wherein the cap holds the switch handle at an OFF-position by pressing the switch handle with an end edge of the cap when the cap is attached to the housing body.
